(19) United States
(12) Patent Application Publication
(10) Pub. No.: US 2022/0190186 A1
(43) Pub. Date: Jun. 16, 2022

(54) OPTOELECTRONIC MODULE

(71) Applicant: ams Sensors Singapore Pte. Ltd., Singapore (SG)

(72) Inventors: Bojan Tesanovic, Eglisau (CH); Ji Wang, Singapore (SG); QiChuan Yu, Singapore (SG); Alexander Bietsch, Thalwil (CH)

(21) Appl. No.: 17/437,607

(22) PCT Filed: Mar. 27, 2020
(86) PCT No.: PCT/SG2020/050179

§ 371 Date: Sep. 9, 2021

Related U.S. Application Data
(60) Provisional application No. 62/825,163, filed on Mar. 28, 2019.

(51) Int. Cl. H01L 31/12; H01L 33/58; H01L 31/0232; H01L 33/48; H01L 31/0203; H01L 31/18

(52) U.S. Cl. CPC H01L 31/12; H01L 33/58; H01L 31/02327; H01L 2933/0058; H01L 31/0203; H01L 31/18; H01L 33/483

(57) ABSTRACT

We disclose an optoelectronic module comprising an optoelectronic device operable to emit or detect a wavelength of radiation, an optical element arranged on the optoelectronic device, the optical element being transparent to the wavelength of radiation capable of being emitted or detected by the optoelectronic device, and a wall configured to laterally enclose the optoelectronic device and the optical element, the wall being opaque to the wavelength of radiation capable of being emitted or detected by the optoelectronic device.

### FIELD

The present disclosure relates to an optoelectronic module, associated apparatuses and methods.

### BACKGROUND

Optoelectronic modules that include one or more optoelectronic devices, such as optical sensors and/or emitters can be integrated, for example, into various types of consumer electronics and other devices, such as mobile phones, smart phones, personal digital assistants (PDAs), tablet computers and laptops, as well as other electronic devices, such as bio devices, mobile robots, and surveillance cameras, among others.

Some devices, such as smartphones, can provide a variety of different optical functions, such as one-dimensional (1D) or three-dimensional (3D) gesture detection, 3D imaging, time-of-flight or proximity detection, ambient light sensing, and/or front-facing two-dimensional (2D) camera imaging. For example, optical proximity detection may be based on emitted light, which is reflected by one or more objects in a scene. The reflected light can be detected by an optical sensor, and photo-generated electrons may be analyzed to determine, for example, whether an object is present in close proximity.

There seems to be a constant need in the industry to improve various aspects of such optoelectronic modules. For example, space in the devices for which the optoelectronic modules are designed often is at a premium. Thus, it is desirable for the optoelectronic modules to be as compact as possible and/or to have a footprint as small as practicable.

### SUMMARY

In general, the present disclosure relates to an optoelectronic module, associated apparatuses and methods. An optical element, which is transparent to a wavelength of radiation, is arranged on an optoelectronic device. The optoelectronic device is operable to emit or detect the wavelength of radiation. The optical element and the optoelectronic device are laterally enclosed by a wall, which is opaque to the wavelength of radiation capable of being emitted or detected by the optoelectronic device.

According to a first aspect of the present disclosure there is provided an optoelectronic module comprising an optoelectronic device operable to emit or detect a wavelength of radiation, an optical element arranged on the optoelectronic device, the optical element being transparent to the wavelength of radiation capable of being emitted or detected by the optoelectronic device, and a wall configured to laterally enclose the optoelectronic device and the optical element, the wall being opaque to the wavelength of radiation capable of being emitted or detected by the optoelectronic device.

By configuring the wall to laterally enclose the optoelectronic device and the optical element, a footprint of the optoelectronic module may be reduced and/or the optoelectronic module may be more compact. The reduced footprint of the optoelectronic module may facilitate integration of the optoelectronic module in another device or apparatus.

Additionally, the wall is opaque to the wavelength of radiation capable of being emitted or detected by the optoelectronic device. As such, the wall may optically isolate the optoelectronic device and the optical element, for example from other optoelectronic devices, which may be capable of emitting or detecting the wavelength of radiation, and/or facilitate handling of the optoelectronic devices.

By configuring the wall to laterally enclose the optoelectronic device and the optical element, the manufacture of the optoelectronic module may be facilitated and/or costs for manufacturing of the optoelectronic module may be reduced. This may be due to a number of manufacturing steps and/or a number of materials used for the manufacture of the optoelectronic module being reduced.

The optical element may be formed from or composed of a curable material. The wall may be formed from or composed of a further curable material.

The optoelectronic module may comprise a connection element for electrically connecting the optoelectronic device to a substrate. The connection element may connect at least a part of the optoelectronic device to the substrate. At least a part of the connection element may extend through at least a part of the optical element and/or the wall.

In some embodiments, the optical element may be arranged on a first surface of the optoelectronic device. The connection element may be arranged on a second surface of the optoelectronic device. The first surface of the optoelectronic device may be opposite to the second surface of the optoelectronic device. In some embodiments, the optoelectronic module may comprise a plurality of connection elements.

The optoelectronic device may comprise a lateral surface. The wall may be configured to contact, e.g. directly contact, the lateral surface. The optical element may be configured to laterally extend beyond at least a part or all of the lateral surface of the optoelectronic device. An interface between the optical element and the wall may comprise a curved, angled, straight, vertical, stepped, elliptical or otherwise profiled shape.

The optoelectronic module may comprises at least two optoelectronic devices operable to emit or detect the wavelength of radiation. The optoelectronic module may comprise at least two optical elements. At least one or each optical element may be arranged on at least one or each of the at least two optoelectronic devices. At least one of the at least two optoelectronic devices may be operable to emit the wavelength of radiation. At least one other of the at least two optoelectronic devices may be operable to detect the wavelength of radiation.

The wall may be configured to laterally enclose each of the at least two optoelectronic devices and each of the at least two optical elements. The wall may be configured to optically separate or isolate the at least two optoelectronic devices from each other. The wall may be configured to optically separate or isolate the at least two optical elements from one another.

Each of the at least two optoelectronic devices may comprise a lateral surface. The wall may be configured to contact, e.g. directly contact, the lateral surface of each of the at least two optoelectronic devices.

At least one of the at least two optical elements may be configured to laterally extend beyond at least a part or all of the lateral surface of at least one of the at least two optoelectronic devices.

According to a second aspect of the present disclosure there is provided a method of manufacturing an optoelectronic module, the method comprising forming an optical element on an optoelectronic device, wherein the optoelectronic device is operable to emit or detect a wavelength of radiation and the optical element is transparent to the wavelength of radiation, and forming a wall so as to laterally enclose the optoelectronic device and optical element, wherein the wall is opaque to the wavelength of radiation capable of being emitted or detected by the optoelectronic device.

The step of forming the optical element may comprise depositing a curable material on the optoelectronic device. The step of forming the optical element may comprise hardening or curing the curable material. The step of forming the optical element may comprise using a replication tool. The step of forming the optical element may comprise selecting an amount of the curable material and/or a shape of the replication tool, e.g. so that the optical element extends beyond at least a part or all of a lateral surface of the optoelectronic device.

The step of forming the wall may comprise laterally enclosing the optoelectronic device and the optical element with a further curable material. The step of forming the wall may comprise hardening or curing the further curable material. The step of forming the wall may comprise depositing the further curable material on a lateral surface of the optoelectronic device, e.g. so that the further curable material contacts, e.g. directly contacts, the lateral surface of the optoelectronic device.

The step of forming the optical element may be carried out before or after the step of forming the wall. In some embodiments, the step of forming the optical element and the step of forming the wall may be carried out sequentially or in parallel.

The method may comprise forming at least two optical elements. Each of the at least two optical elements may be formed on each of at least two optoelectronic devices. Each of the at least two optoelectronic devices may be operable to emit or detect the wavelength of radiation. Each of the at least two optical elements may be transparent to the wavelength of radiation. The method may comprise forming the wall so as to laterally enclose each of the at least two optoelectronic devices and/or each of the at least two optical elements.

The step of forming the wall may comprise forming the wall so that the wall optically separates or isolates the at least two optoelectronic devices from one another. The step of forming the wall may comprise forming the wall so that the wall optically separates or isolates the at least two optical elements from one another.

According to a third aspect of the present disclosure there is provided an apparatus comprising an optoelectronic module according to the first aspect, wherein the apparatus is at least one of: a portable computing device, a cellular telephone, a camera, an image-recording device; and/or a video recording device or the like.

According to a fourth aspect of the present disclosure there is provided an apparatus comprising a first optoelectronic die operable to emit or detect a wavelength of light, a first aperture over the first optoelectronic die, the first aperture composed of a first epoxy material that is transparent to the wavelength of light, a second epoxy material laterally surrounding the first aperture and the first optoelectronic die, the second epoxy material being in contact with the sidewalls of the first optoelectronic die, and a wire bond attached to the first optoelectronic die and at least partially encased by the first epoxy material or the second epoxy material.

The first epoxy material may extend laterally beyond at least one sidewall of the first optoelectronic die. None of the first epoxy material may be present on sidewalls of the first optoelectronic die.

The first optoelectronic die may be operable to emit the wavelength of light. The apparatus may further include or comprise a second optoelectronic die operable to detect the wavelength of light and a second aperture over the second optoelectronic die. The second aperture may be composed of the first epoxy material. The second epoxy material may laterally surround the second aperture and the second optoelectronic die. The second epoxy material may be in contact with the sidewalls of the second optoelectronic die. The second epoxy material may optically separate the first and second optoelectronic dies from one another. The second epoxy material may optically separate the first and second apertures from one another.

The first epoxy material may extend laterally beyond at least one sidewall of the first optoelectronic die or the second optoelectronic die.

An interface between at least one of the first or second aperture and the second epoxy material may be curved. An interface between at least one of the first or second aperture and the second epoxy material may be elliptical.

The apparatus may further include or comprise a wire bond attached to the second optoelectronic die. The wire bond may be at least partially encased by the first epoxy material or the second epoxy material. The wire bond may be at least partially encased by the first epoxy material.

According to a fifth aspect there is provided a method comprising depositing a first epoxy material on a light-emission surface of a first optoelectronic die and on a light-receiving surface of a second optoelectronic die, wherein the first optoelectronic die is operable to emit a wavelength of light, and the second optoelectronic die is operable to detect the wavelength of light, curing the first epoxy material to form respective apertures on the first and second optoelectronic dies, wherein the cured first epoxy material is transparent to the wavelength of light, subsequently providing a second epoxy material in spaces laterally surrounding the first and second apertures and the first and second optoelectronic dies, the second epoxy material being in contact with the sidewalls of the first and second optoelectronic dies, optically separating the first and second optoelectronic dies from one another, and optically separating the first and second apertures from one another, wherein at least one wire bond attached to the first optoelectronic die or the second optoelectronic die is at least partially encased by the first epoxy material or the second epoxy material.

The method may include depositing the first epoxy material on the light-emission surface of the first optoelectronic die and on the light-receiving surface of the second optoelectronic die using a replication tool. The first epoxy material may form a meniscus that limits the flow of the first epoxy material prior to curing the first epoxy material.

The first epoxy material may extend laterally beyond at least one sidewall of the first or second optoelectronic dies without flowing down the sidewalls of the first and second optoelectronic dies.

Various aspects and features of the present disclosure set out above or below may be combined with various other aspects and features of the present disclosure as will be readily apparent to the skilled person.

### BRIEF DESCRIPTION OF THE DRAWINGS

Some preferred embodiments of the disclosure will now be described by way of example only and with reference to the accompanying drawings, in which:

FIG. 1 depicts an exemplary optoelectronic module in accordance with the present disclosure;

FIG. 2 depicts another exemplary optoelectronic module;

FIG. 3 depicts another exemplary optoelectronic module;

FIG. 4 depicts another exemplary optoelectronic module;

FIG. 5 depicts an exemplary flow diagram outlining the steps of a method of manufacturing the optoelectronic module of any one of FIGS. 1 to 4;

FIG. 6 depicts an exemplary process that may be used for forming an optical element on an optoelectronic device;

FIG. 7 depicts another exemplary process that may be used for forming an optical element on an optoelectronic device; and

FIG. 8 depicts an exemplary process that may be used for forming a wall of the optoelectronic module of FIG. 3 or 4.

### DETAILED DESCRIPTION

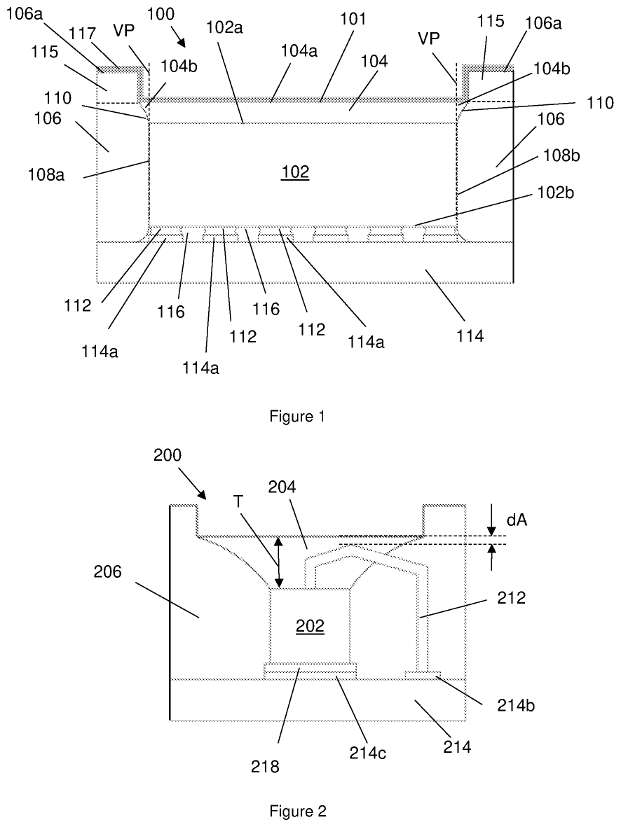

FIG. 1 shows an exemplary optoelectronic module 100. The optoelectronic module 100 comprises an optoelectronic device 102 operable to emit or detect a wavelength of radiation. For example, the optoelectronic device 102 may be provided in the form of an emitter, such as for example a light emitting diode (LED) infra-red (IR) LED, organic LED (OLED), a laser diode, infra-red (IR) laser, a vertical cavity surface emitting laser (VCSEL), or the like. The emitter may be configured to emit radiation having a wavelength in, for example, the visible or infrared spectrum. The emitter may comprise or be formed from a semiconductor material, such as for example silicon or the like, or from a compound semiconductor material, such as for example gallium arsenide (GaAs), indium arsenide (InAs) and/or the like.

In some embodiments, the optoelectronic devices 102 may be provided in the form of a detector or sensor, such as a photodetector, photodiode, image sensor, e.g. a complementary metal-oxide-semiconductor (CMOS) sensor or charge coupled device CCD, photomultiplier, single photon avalanche diode or the like. The detector may comprise a plurality of radiation sensitive elements, such as for example a plurality of pixels. The radiation sensitive elements may be arranged, e.g. spatially distributed, to form an array. The detector may be configured to detect or sense radiation having a wavelength in, for example, the visible or infrared spectrum. It will be appreciated that the detector or sensor may comprise logic and/or electronic elements for reading and/or processing one or more signals from the detector. The pixels, logic and/or electronic elements may be implemented, for example in an integrated chip or device, such as an integrated semiconductor chip or the like.

The optoelectronic module 100 comprises an optical element 104 arranged on the optoelectronic device 102. The optical element 104 may be arranged on a part or all of a first surface 102a, e.g. a top surface, of the optoelectronic device 102. The first surface 102a of the optoelectronic device 102 may define a radiation emitting or radiation receiving surface. In this embodiment, the optical element 104 is arranged on all of the first surface 102a of the optoelectronic device 102.

The optical element 104 is transparent, e.g. substantially transparent, to the wavelength of radiation capable of being emitted or detected by the optoelectronic device 102. For example, the optical element 104 may be transparent to radiation having a wavelength or wavelength range in the visible spectrum and/or in the near-infrared spectrum. The optical element 104 may have a flat surface 104a, e.g. a flat top surface. The optical element 104 may be configured to limit the maximum size of a radiation beam that can pass to or from the optoelectronic device 102. In the embodiment shown in FIG. 1, the optical element 104 is provided in the form of an aperture. It will be appreciated that in other embodiments the optical element may be provided in the form of a lens, such as a convex or concave lens, or an array of lenses, such as an array of microlenses. In embodiments, where the optical element is provided in the form of the lens or array of lenses, at least a part or all of the surface, e.g. the top surface, of the optical element may be shaped or curved.

The optical element 104 may be formed from a curable material, such as a polymer material. In this embodiment, the curable material comprises a first epoxy material such as a clear epoxy material. However, it will be appreciated that in other embodiments the curable material may comprise another polymer material, such as acrylate, perfluoropolyether (PFPE) or another curable material.

The optoelectronic module 100 comprises a wall 106. The wall 106 is configured to laterally enclose the optoelectronic device 102 and the optical element 104. Expressed differently, the wall 106 may be arranged to laterally surround the optoelectronic device 102 and the optical element 104. The wall 106 is opaque to the wavelength of radiation capable of being emitted or detected by the optoelectronic device. For example, the wall 106 may be configured to absorb radiation having a wavelength or wavelength range in the visible spectrum and/or in the near-infrared spectrum. The wall 106 may be formed from a further curable material, such as a polymer material. In this embodiment, the further curable material comprises a second epoxy material, such as a black and/or opaque epoxy material. However, it will be appreciated that in other embodiments the curable material may comprise another polymer material, such as acrylate, perfluoropolyether (PFPE) or another curable material.

By configuring the wall 106 to laterally enclose the optoelectronic device 102 and the optical element 104, a footprint of the optoelectronic module may be reduced and/or the optoelectronic module 100 may be more compact. The reduced footprint of the optoelectronic module 100 may facilitate integration of the optoelectronic module 100 in another device or apparatus. Additionally, the wall 106 is opaque to the wavelength of radiation capable of being emitted or detected by the optoelectronic device 102. As such, the wall 106 may optically isolate the optoelectronic device 102 and the optical element 104, for example from other optoelectronic devices, which may be capable of emitting or detecting the wavelength of radiation, and/or facilitate handling of the optoelectronic devices 102. By configuring the wall 106 to laterally enclose the optoelectronic device 102 and the optical element 104, the manufacture of the optoelectronic module 100 may be facilitated and/or costs for manufacturing of the optoelectronic module 100 may be reduced. This may be due to a number of manufacturing steps and/or a number of materials used for the manufacture of the optoelectronic module 100 being reduced.

The optoelectronic device 102 may comprise a lateral surface 108a. The lateral surface 108a may be defined by one or more sidewalls 108b of the optoelectronic device 102. The wall 106 is configured to contact, e.g. directly contact, the lateral surface 108a, e.g. the sidewalls 108b.

As can be seen from FIG. 1, the optical element 104 is configured to laterally extend beyond at least a part or all of the lateral surface 108a of the optoelectronic device 102. Expressed differently, the optical element 104 may be configured to laterally extend beyond at least some or all of the sidewalls 108b of the optoelectronic device 102. Expressed in a further way, the optical element 104 may comprise one or more portions 104b, which may extend beyond a vertical plane VP, which is indicated in FIG. 1 by dashed lines, of some or all of the sidewalls 108b of the optoelectronic device 102. The portions 104b of the optical element 104 that extend beyond the vertical plane VP of some or all of the sidewalls 108b may be referred to as “yards.” It will be appreciated that, in this embodiment at least, no part of the optical element 104 extends along the lateral surface 108a, e.g. the sidewalls 108b, of the optoelectronic device 102. However, in other embodiments, a portion of the optical element 104 may extend at least partly along the lateral surface 108a.

As can be seen in FIG. 1, an interface 110 between the optical element 104 and the wall 106 may comprise a curved or elliptical shape. It will be appreciated that in other embodiments, the interface between the optical element and the wall may comprise an angled, straight, vertical, stepped or otherwise profiled shape.

The optoelectronic module 100 may comprise one or a plurality of connection elements 112 for electrically connecting the optoelectronic device 102 to a substrate 114, such as a flexible cable, printed circuit board (PCB), ceramic or lead frame or the like. In this embodiment, the connection elements 112 are provided in the form of solder balls or solder bumps.

The substrate 114 may comprise one or a plurality of further connection elements 114a. The further connection elements 114a may be provided in the form of conductive pads or plates or the like. The further connection elements 114a may comprise a metal or metal alloy, such as for example copper, aluminum, silver, gold or the like. The further connection elements 114a may be configured for electrically connecting the optoelectronic device 102 to the substrate 114, e.g. via the connection elements 112. The connection elements 112 may be arranged so that each connection element 112 is in contact with a respective further connection element 114a.

A gap 116 between each of the connection elements 112 and/or the further connection elements 114 may be filled with an underfill material. The underfill material may comprise a polymer material. The polymer material may comprise silicon or silica particles, e.g. to compensate for different coefficients of thermal expansion between the optoelectronic device 102, the connections elements 112 and/or the further connection elements 114a.

The optical element 104 may be arranged on the first surface 102a of the optoelectronic device 102 and the connection elements 112 may be arranged on a second surface 102b of the optoelectronic device 102. The first surface of the optoelectronic device 102 may be opposite to the second surface of the optoelectronic device 102. As described above, the first surface 102a comprises a top surface of the optoelectronic device 102. The second surface 102b comprises a bottom surface of the optoelectronic device 102.

The optoelectronic module 100 may comprise a coating 117. The coating may be arranged on the wall 106, e.g. a surface or top surface 106a thereof, and the optical element 104. In other words, the coating 117 may extend across an upper surface 101 of the optoelectronic module 100, as shown in FIG. 1. The coating may be configured to filter or block radiation having a wavelength that is different to the wavelength of radiation capable of being emitted or detected by the optoelectronic device 102. In some embodiments, the coating may be configured to filter or block a portion of the radiation capable of being emitted or detected by the optoelectronic device. In such embodiments, the coating may only extend across the wall and/or a part of the optical element 104. In such embodiments, the coating may act or function as an aperture. It will be appreciated that in other embodiments the coating may only extend across a part or all of the optical element. Although the coating 117 is only shown in FIG. 1, it will be appreciated that any of the optoelectronic modules described herein may comprise a coating.

The optoelectronic module 100 may comprise one or more baffle elements 115. The baffle elements 115 may be part of or comprised in the wall 106. The baffle elements 115 may be configured to extend beyond the surface 104a of the optical element 104. The baffle elements 115 may be configured to optically isolate, e.g. further optically isolate, the optoelectronic device 102 and the optical element 104, for example from other optoelectronic devices, which may be capable of emitting or detecting the wavelength of radiation.

FIG. 2 shows another exemplary optoelectronic module 200. The optoelectronic module 200 shown in FIG. 2 is similar to the optoelectronic module shown in FIG. 1. Any features describes in relation to the optoelectronic module 100 in FIG. 1 may also apply to the optoelectronic module 200 shown in FIG. 2. Only differences between the optoelectronic modules 100, 200 shown in FIGS. 1 and 2, respectively, will be described in the following.

The optoelectronic module 200 may comprise a connection element 212 for electrically connecting at least a part of the optoelectronic device 202 to the substrate 214. For example, the connection element 212 may be configured to connect at least one electrode of the optoelectronic device 202 to the substrate 214. In this embodiment, the connection element 212 may be provided in the form of a wire bond. At least a part of the connection element 212 extends through at least part of the optical element 104. The optical element 204 may encase and/or protect the part of the connection element 212. It will be appreciated that in other embodiments a part of the connection element may additionally or alternatively extend through at least a part of the wall. The optical element 204 and/or the wall 206 may encase and/or protect the part of the connection element 212. A thickness T of the optical element 204 may be selected so as to prevent damage to the connection element 212, e.g. during manufacture of the optoelectronic module 200. For example, as shown in FIG. 2, the optical element 204 may have a thickness dA above a plane of an uppermost section of the connection element 212.

The substrate 214 may comprise a first further connection element 214b for electrically connecting the connection element 212 to the substrate 214. The substrate 214 may comprise a second further connection element 214c for connecting another part of the optoelectronic device 202 to the substrate 214. For example, the further connection element 214c may be configured to connect at least one other electrode of the optoelectronic device 202 to the substrate 214. The first and second further connection elements 214b, 214c may each be provided in the form of a conductive pad or plate. The first and second further connection elements 214b, 214c may each comprise a metal or metal alloy, such as for example copper, aluminum, silver, gold or the like.

A bonding layer 218 may be arranged between the optoelectronic device 202 and the second further connection element 214c of the substrate 214. The bonding layer 218 may be configured to bond or connect the optoelectronic device 202 to the second further connection element 214c of the substrate 214. The bonding layer 218 may comprise a conductive material. The conductive material may comprise a conductive polymer material, such as a conductive epoxy or the like.

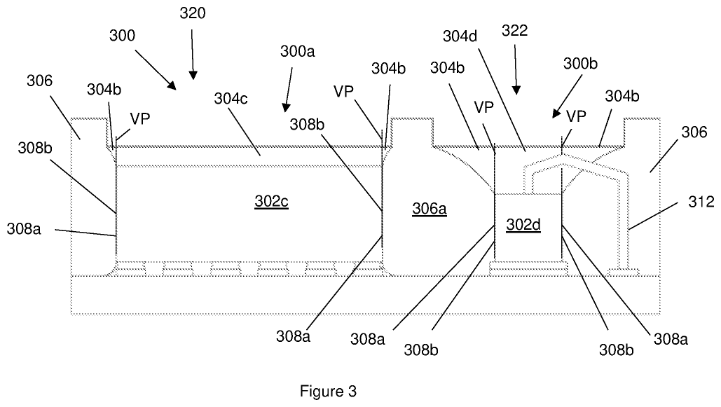

FIG. 3 shows another exemplary optoelectronic module 300. The optoelectronic module 300 comprises at least two optoelectronic devices 302c, 302d operable to emit or detect the wavelength of radiation. The optoelectronic module 300 comprises at least two optical elements 304c, 304d. Each optical element 304c, 304d is arranged, respectively, on one of the at least two optoelectronic devices 302c, 302d.

The optoelectronic module 300 may be considered as comprising a first submodule 300a and a second submodule 300b. The first submodule 300a may be provided in the form of the optoelectronic module 100 shown in FIG. 1. The second submodule 300b may be provided in the form of the optoelectronic module 200 shown in FIG. 2. As such, any features described above in relation to FIGS. 1 and 2 may also apply to the optoelectronic module 300 shown in FIG. 3, e.g. the first and second submodules 300a, 300b.

At least one of the at least two optoelectronic devices 302c, 302d may be operable to emit the wavelength of radiation and at least one other of the at least two optoelectronic devices 302c, 302d may be operable to detect the wavelength of radiation. For example, in this embodiment, the optoelectronic device 302c of the first submodule 300a is provided in the form of a detector or sensor. The optoelectronic device 302d of the second submodule 300b is provided in the form of an emitter. As such, the optoelectronic module 300 may be considered as comprising a radiation detection channel 320 and a radiation emission channel 322. For example, when the optoelectronic module described herein is used as part of a proximity sensor, radiation emitted by the emitter may be directed out of the second submodule 300b and, if reflected by an object back toward the radiation detection channel 320, may be sensed or detected by the detector of the first submodule 300a.

The wall 306 is configured to laterally enclose each of the two optoelectronic devices 302c, 302d and each of the two optical elements 304c, 304d. The wall 306 is configured to optically separate or isolate the two optoelectronic devices 302c, 302d from each other. The wall is additionally configured to optically separate or isolate the two optical elements 304c, 304d from one another. For example, an interior portion 306a of the wall 306 provides optical isolation between the first and second submodules 300a, 300b, e.g. the radiation detection channel 320 and the radiation emission channel 322. As shown in FIG. 3, the interior portion 306a of the wall 306 completely fills the space between the two optoelectronic devices 302c, 302d and the two optical elements 304c, 304d.

Each of the two optoelectronic devices 302c, 302d comprises a lateral surface 308a. The wall 306 is configured to contact, e.g. directly contact, the lateral surface 308a of each of the two optoelectronic devices 302c, 302d. In other words, the wall 306 laterally surrounds each of the two optoelectronic devices 302c, 302d and is in contact, e.g. direct contact, with one or more sidewalls 308b of each of the two optoelectronic devices 302c, 302d.

At least one of the two optical elements 304c, 304d may be configured to laterally extend beyond at least a part or all of the lateral surface 308a of at least one of the two optoelectronic devices 302c, 302d. In the embodiment shown in FIG. 3, each of the two optical elements 304c, 304d laterally extends beyond the lateral surface 308a of each of the two optoelectronic devices 302c, 302d. As described above, each of the two optical elements 304c, 304d may comprise one or more portions 304b, which may extend beyond a vertical plane VP, which is indicated in FIG. 3 by dashed lines, of some or all of the sidewalls 308b of each of the two optoelectronic devices 302c, 302d.

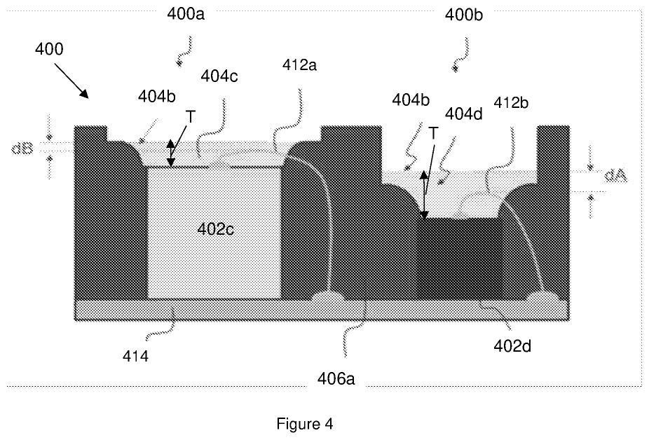

FIG. 4 shows another exemplary optoelectronic module 400. The optoelectronic module shown in FIG. 4 is similar to the optoelectronic module shown in FIG. 300. Any features described in relation to the optoelectronic module 300 in FIG. 3 may also apply to the optoelectronic module 400 shown in FIG. 4. Only differences between the optoelectronic modules 300, 400 shown in FIGS. 3 and 4, respectively, will be described in the following.

As described above, the optoelectronic module 400 may comprise a connection element 412a, 412b for electrically connecting at least a part of each of the two optoelectronic devices 402c, 402d to the substrate 414. The part of each of the two optoelectronic devices 402c, 402d may comprise at least one electrode of each of the two optoelectronic devices 402c, 402d. In this embodiment, each connection element 412a, 412b is provided in the form of a wire bond.

At least a part of each connection element 412a, 412b extends through at least part of each of the two the optical elements 404c, 404d. Each of the two optical elements 404c, 404d may encase and/or protect a part of each connection element 412a, 412b. It will be appreciated that a part of each connection element 412a, 412b may additionally extend through at least a part of the wall 406. Each of the two optical elements 404c, 404d and/or the wall 406 may encase and/or protect the part of each connection element 412a, 412b. A thickness T of each of the two optical element 404c, 404d may be selected so as to prevent damage to each connection element 412a, 412b, e.g. during manufacture of the optoelectronic module 400. For example, as shown in FIG. 4, the optical element 404c of the first submodule 400a may have a thickness dB above the plane of the uppermost section of the connection element 412a and the optical element 404d of the second submodule 400b may have a thickness dA above the plane of the uppermost section of the connection element 412b.

Although not shown in FIG. 4, it will be appreciated that another part, e.g. at least one other electrode, of each of the two optoelectronic devices may be electrically connected to the substrate, e.g. using a respective further connection element and/or a respective bond layer, as described above in relation to FIG. 2.

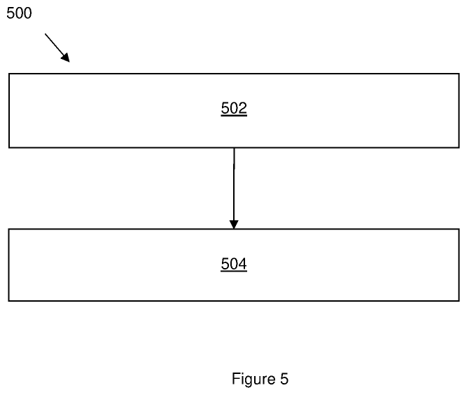

FIG. 5 shows an exemplary flow diagram outlining the steps of a method 500 of manufacturing an optoelectronic module. In step 502, the method comprises forming an optical element on an optoelectronic device. The optoelectronic device is operable to emit or detect a wavelength of radiation. The optical element is transparent to the wavelength of radiation capable of being emitted or detected by the optoelectronic device. As described above, the optoelectronic device may be provided in the form of an emitter, a detector or sensor.

In step 504, the method comprises forming a wall so as to laterally enclose the optoelectronic device and optical element. The wall is opaque to the wavelength of radiation capable of being emitted or detected by the optoelectronic device.

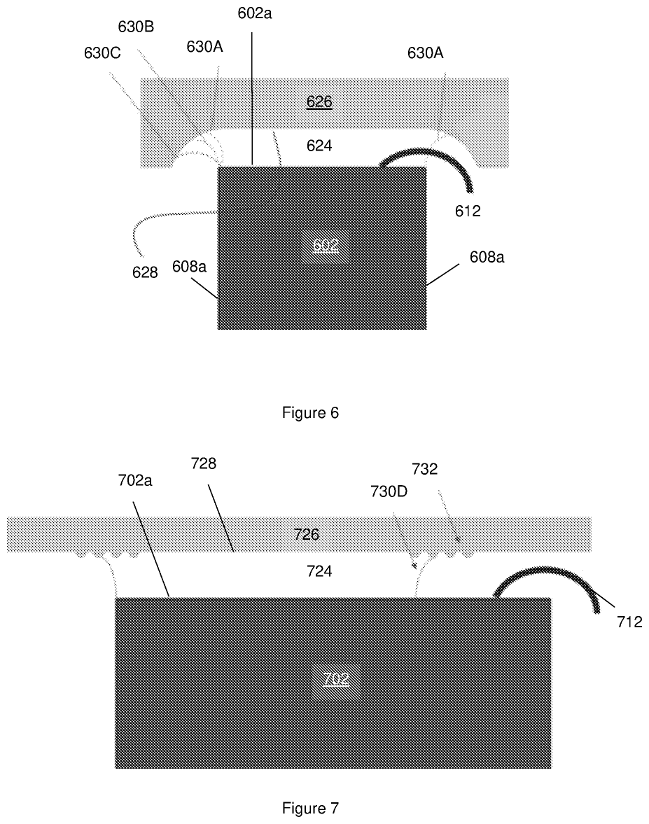

Step 502 of the method 500 will be described below with reference to FIGS. 6 and 7. FIGS. 6 and 7 each depict an exemplary process that may be used for forming an optical element on an optoelectronic device.

The step of forming the optical element (502) may comprise depositing a curable material 624 on the optoelectronic device 602. The curable material may be deposited on at least a part or all of the optoelectronic device, e.g. the first surface 602a thereof. The curable material 624 may be formed on the optoelectronic device 602 using a replication tool 626, e.g. a mold or the like. For example, the curable material 624 may be deposited, e.g. by jetting or needle dispensing, onto or through a surface 628, such as a molding surface, of the replication tool 626. An amount of the curable material 624 and/or a shape of the replication tool 626, e.g. a shape of the surface 628, may be selected so that the optical element to be formed (not shown FIG. 6) extends beyond at least a part or all of a lateral surface 608a of the optoelectronic device 602. The curable material 624 may extend beyond the part or all of the lateral surface 608a of the optoelectronic device 602, e.g. due to capillary forces between the curable material 624 and the replication tool 626.

The surface 628 of the replication tool may comprise or be composed, for example, of polydimethylsiloxane (PDMS), stainless steel, or glass. Subsequent to or prior to depositing the curable material 624 on the surface 628, the replication tool 626 may be moved toward the first surface 602a of the optoelectronic device 602, e.g. so as to press the curable material 624 onto the optoelectronic device 602, e.g. onto at least part or all of the first surface 602a thereof. In the embodiment shown in FIG. 6, the curable material 624 is deposited onto all of the first surface 602a of the optoelectronic device 602.

As described above, the amount of the curable material 624 and/or the shape of the surface 628 of the replication tool 626 may be selected so as to control the flow of the curable material 624 in a predefined manner. For example, as shown in FIG. 6, in some instances, the curable material 624 may form a meniscus such that at least a portion of the optical element to be formed extends beyond the lateral surface 608a of the optoelectronic device 602. The portion of the optical element to be formed may have or define a curved or an elliptical profile at a first position 630A.

In other instances, the shape of the surface 628 of the replication tool 626 and/or the amount of curable material 624 may be selected so that so that a boundary of the portion of the formed optical element extends to another position, such as a second position 630B or a third position 630C. One or more other parameters of the method, e.g. step 502, may be selected so that the curable material 624 encases a part of the connection element 612, which in this embodiment is provided in the form of a wire bond.

By forming a portion of the optical element to extend beyond the lateral surface 608a of the optoelectronic device 602, handling of different tolerances in the sizes of the optoelectronic devices may be facilitated. The method disclosed herein may also prevent the curable material 624 from flowing down the lateral surface 608a of the optoelectronic device 602. This may be desirable to help prevent or limit crosstalk between a first submodule and a second submodule in examples where the optoelectronic module comprises at least two optoelectronic devices, as described above.

Referring to FIG. 7, a replication tool 726 may have a plurality of elements 732 on the surface 728, which, in use, may face the optoelectronic device 702. The elements 732 may be configured to limit or control the flow of the curable material 724. In the embodiment shown in FIG. 7, the curable material 724 forms a meniscus at position 730D such that it does not encase any part of the connection element 712. In other words, the optical element may be formed on a part of the optoelectronic device 702, e.g. a part of the first surface 702a thereof. The connection element 712 may be arranged on another part of the optoelectronic device 702, e.g. another part of the first surface 702a thereof, and spaced from the curable material 724.

In this embodiment, the connection element may subsequently be encased by the further curable material, e.g. during the formation of the wall, as described below. In other words, the connection element 712 may extend through at least a part of the wall.

For example, subsequently to depositing the curable material 624, 724 on the optoelectronic device 602, 702, the curable material 624, 724 may be hardened, e.g. using thermal and/or UV curing. This may result in the formation of the optical elements, as described above.

The method 500 may comprise forming at least two optical elements. Each of the two optical elements may be formed on each of at least two optoelectronic devices. It will be appreciated that any of the steps described above may be used to form the two optical elements.

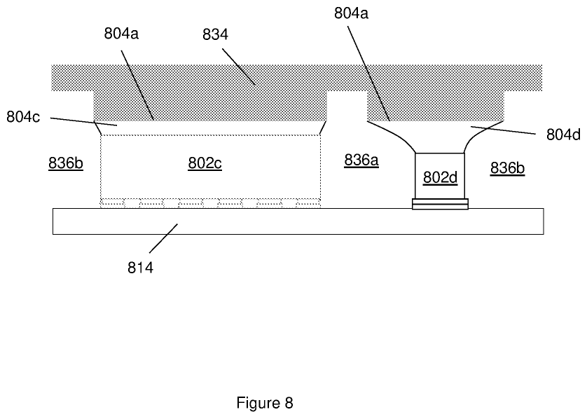

Step 504 of method 500 shown in FIG. 5 will be described with reference to FIG. 8. FIG. 8 depicts an exemplary process that may be used for forming the wall of the optoelectronic module. FIG. 8 shows two optoelectronic device 802c, 802d, which are arranged spaced from each other. An optical element 804c, 804d is formed, respectively, on each of the two optoelectronic devices 802c, 802d. It will be appreciated that the two optoelectronic devices 802c, 802d may be electrically connected to the substrate 814, e.g. prior to the step of forming the wall (504).

The wall may be formed so as to laterally enclose each of the two optoelectronic devices 802c, 802d and each of the two optical elements 804c, 804d. A supporting member 834 may be arranged on the two optical elements 804c, 804d. A space 836a may extend between the two optoelectronic devices 802c, 802d and the two optical elements 804c, 804d. One or more further spaces 836b may extend between the supporting member 834 and the substrate 814. The space 836a and the further spaces 836b may laterally surround each optoelectronic device 802c, 802d and each optical element 804c, 804d. The space 836a and the further spaces 836b may be injected or filled with the further curable material. The space 836a between the two optoelectronic devices 802c, 802d and the two optical elements 804c, 804d may be filled or injected with the further curable material to form the interior portion of the wall. The wall may be formed so that the wall optically separates or isolates the two optoelectronic devices 802c, 802d from one another and so that the wall optically separates or isolates the two optical elements 804c, 804d from one another. The further curable material may be injected in the space 836a and the further spaces 836b using a vacuum injection molding (VIM) process or an injection molding process or the like.

For example, subsequently to injecting the further curable material into the space 836a and the further spaces 836b, the further curable material may be hardened, e.g. using thermal and/or UV curing. This may result in the formation of the wall, as described above.

The supporting member 834 may be configured to mold at least part of the further curable material. For example, the method 500 may comprise forming one or more baffle elements. The baffle elements may be formed to extend beyond the surface 804a of each optical element 804c, 804d. The supporting member 834 may be configured to allow for the formation of the one or more baffle elements. For example, the supporting member 834 may be shaped so that a portion of the further curable material extends beyond the surface 804a of each optical element 804c, 804d, e.g. when the further curable material is filled or injected into the space 834a or the further spaces 834b.

It will be appreciated that in some embodiments, the optoelectronic module comprises a single optoelectronic device and a single optical element. Any of the method steps described above may be used to form the optoelectronic module. For example, in such embodiments, the step of forming the wall (504) may comprise laterally enclosing the optoelectronic device and the optical element with the further curable material. The further curable material may be deposited on the lateral surface of the optoelectronic device so that the further curable material contacts the lateral surface of the optoelectronic device. The optoelectronic device and the optical element may be laterally enclosed by the further curable material, e.g. by injecting or filling the further curable material into one or more spaces between the supporting member and the substrate.

Any of the steps of the method 500 may be performed as part of a wafer-level process, in which multiple (e.g., tens, hundreds, or even thousands) of optoelectronic modules are formed or processed at the same time in parallel.

Any of optoelectronic modules described above may be integrated in an apparatus, such as at least one of: a portable computing device, a cellular telephone, a camera, an image-recording device; and/or a video recording device. For example, any of the optoelectronic module described above may be part of or comprised in a sensor or module of the apparatus, such as for example a proximity sensor, time of flight sensor, distance sensor, spectral sensor, an optical module, e.g. datacom module, or other sensor or module.

The substrate 114, 214, 314, 414, 814 may be connected electrically to other components within the apparatus. The apparatus may include one or more processors, one or more memories (e.g. RAM), storage (e.g., a disk or flash memory), a user interface (which may include, e.g., a keypad, a TFT LCD or OLED display screen, touch or other gesture sensors, a camera or other optical sensor, a compass sensor, a 3D magnetometer, a 3-axis accelerometer, a 3-axis gyroscope, one or more microphones, etc., together with software instructions for providing a graphical user interface), interconnections between these elements (e.g., buses), and an interface for communicating with other devices (which may be wireless, such as GSM, 3G, 4G, CDMA, WiFi, WiMax, Zigbee or Bluetooth, and/or wired, such as through an Ethernet local area network, a T-1 internet connection, etc.).

The optoelectronic module's control and processing circuitry (e.g., an electronic control circuit) can be implemented, for example, as one or more integrated circuits in one or more semiconductor chips with appropriate digital logic and/or other hardware components (e.g., read-out registers; amplifiers; analog-to-digital converters; clock drivers; timing logic; signal processing circuitry; and/or a microprocessor). The control and processing circuitry, and associated memory, may reside in the same semiconductor chip as the detector or in one or more other semiconductor chips. In some instances, the control and processing circuitry may be external to the module; for example, the control and processing circuitry can be integrated into a processor for the apparatus in which the optoelectronic module is disposed.

### LIST OF REFERENCE NUMERALS

100, 200, 300, 400 optoelectronic module
101 upper surface of optoelectronic module
300a, 400a first submodule
300b, 400b second submodule
102, 202, 302c, 302d, 402c, 402d,
602, 702, 802c, 802d optoelectronic device
102a, 202a, 602a, 702a first surface of optoelectronic device
102b second surface of optoelectronic device
104, 204, 304c, 304d, 404c, 404d optical elements
104a, 204a, 702a surface of optical element
104b, 204b, 304b, 404b, 804c, 804d portions of optical element
106, 206, 306, 406 wall
306a, 406a interior portion of wall
106a surface of wall
108a, 208a, 308a, 408a, 608a lateral surface of optoelectronic device
108b, 208b, 308b, 408b, 608b sidewalls of optoelectronic device
110 interface
112, 212, 312, 412a, 412b, 612, 712 connection element
114, 214, 314, 414, 814 substrate
114a further connection elements
214b first further connection element
214c second further connection element
115 baffle elements
117 coating
218 bonding layer
320 radiation detection channel
322 radiation emission channel
502, 504 method steps
624, 724 curable material
630A, 630B, 630B, 730D positions
628, 728 replication tool
732 elements
834 supporting member
836a space
836b further spaces
T thickness
VP vertical plane

It will be appreciated that the terms “detector or sensor” may be considered as encompassing the terms “receiver or light receiver.” These terms may be used interchangeably.

It will appreciated that the terms “radiation” and “light” may be interchangeably used.

The term “optoelectronic device” may be considered as encompassing the term “optoelectronic die.” The term “optoelectronic device” and “optoelectronic die” may be interchangeably used.

It will be appreciated that one or more steps of the methods and/or process flows described above may be used in combination or in isolation.

It will be understood that references to a plurality of features may be interchangeably used with references to singular forms of those features, such as for example “at least one” and/or “each”. Singular forms of a feature, such as for example “at least one” or “each,” may be used interchangeably.

The skilled person will understand that in the preceding description and appended claims, positional terms such as ‘above’, ‘overlap’, ‘under’, ‘lateral’, etc. are made with reference to conceptual illustrations of an apparatus, such as those showing standard cross-sectional perspectives and those shown in the appended drawings. These terms are used for ease of reference but are not intended to be of limiting nature. These terms are therefore to be understood as referring to a device when in an orientation as shown in the accompanying drawings.

Although the disclosure has been described in terms of embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the disclosure, whether alone or in any appropriate combination with any other feature disclosed or illustrated herein.

1. An optoelectronic module comprising:
an optoelectronic device operable to emit or detect a wavelength of radiation;
an optical element arranged on the optoelectronic device, the optical element being transparent to the wavelength of radiation capable of being emitted or detected by the optoelectronic device; and
a wall configured to laterally enclose the optoelectronic device and the optical element, the wall being opaque to the wavelength of radiation capable of being emitted or detected by the optoelectronic device.

2. The optoelectronic module according to claim 1, wherein the optical element is formed from a curable material and/or the wall is formed from a further curable material.

3. The optoelectronic module according to claim 1, comprising a connection element for electrically connecting at least a part of the optoelectronic device to a substrate, and wherein at least a part of the connection element extends through at least a part of the optical element and/or the wall.

4. The optoelectronic module according to claim 1, comprising a plurality of connection elements for electrically connecting the optoelectronic device to a substrate, the optical element being arranged on a first surface of the optoelectronic device and at least one of the plurality of connection elements being arranged on a second surface of the optoelectronic device, the first surface of the optoelectronic device being opposite to the second surface of the optoelectronic device.

5. The optoelectronic module according to claim 1, wherein the optoelectronic device comprises a lateral surface and the wall is configured to contact the lateral surface.

6. The optoelectronic module according to claim 5, wherein the optical element is configured to laterally extend beyond at least a part or all of the lateral surface of the optoelectronic device.

7. The optoelectronic module according to claim 1, wherein an interface between the optical element and the wall comprises a curved shape.

8. The optoelectronic module according to claim 1, comprising:
at least two optoelectronic devices operable to emit or detect the wavelength of radiation; and
at least two optical elements, each optical element being arranged on each of the at least two optoelectronic devices.

9. The optoelectronic module according to claim 8, wherein at least one of the at least two optoelectronic devices is operable to emit the wavelength of radiation and at least one other of the at least two optoelectronic devices is operable to detect the wavelength of radiation.

10. The optoelectronic module according claim 8, wherein the wall is configured to laterally enclose each of the at least two optoelectronic devices and each of the at least two optical elements; and/or to optically separate the at least two optoelectronic devices from each other; and/or to optically separate the at least two optical elements from one another.

11. (canceled)

12. The optoelectronic module according to claim 8, wherein each of the at least two optoelectronic devices comprises a lateral surface and the wall is configured to contact the lateral surface of each of the at least two optoelectronic devices.

13. The optoelectronic module according to claim 12, wherein at least one of the at least two optical elements is configured to laterally extend beyond at least a part or all of the lateral surface of at least one of the at least two optoelectronic devices.

14. A method of manufacturing an optoelectronic module, the method comprising:
forming an optical element on an optoelectronic device, wherein the optoelectronic device is operable to emit or detect a wavelength of radiation and the optical element is transparent to the wavelength of radiation; and
forming a wall so as to laterally enclose the optoelectronic device and optical element, wherein the wall is opaque to the wavelength of radiation capable of being emitted or detected by the optoelectronic device.

15. The method according to claim 14, wherein the step of forming the optical element comprises depositing a curable material on the optoelectronic device and hardening the curable material.

16. The method of claim 15, wherein the step of forming the optical element comprises using a replication tool.

17. The method of claim 16, wherein the step of forming the optical element comprises selecting an amount of the curable material and/or a shape of the replication tool so that the optical element extends beyond at least a part or all of a lateral surface of the optoelectronic device.

18. The method according to claim 14, wherein the step of forming the wall comprises laterally enclosing the optoelectronic device and the optical element with a further curable material and hardening the further curable material.

19. The method according to claim 18, wherein the step of forming the wall comprises depositing the further curable material on a lateral surface of the optoelectronic device so that the further curable material contacts the lateral surface of the optoelectronic device.

20. The method according to claim 14, wherein the method comprises:
forming at least two optical elements, each of the at least two optical elements being formed on each of at least two optoelectronic devices, each of the at least two optoelectronic devices being operable to emit or detect the wavelength of radiation and each of the at least two optical elements being transparent to the wavelength of radiation; and
forming the wall so as to laterally enclose each of the at least two optoelectronic devices and each of the at least two optical elements;
and/or to optically separate the at least two optoelectronic devices from one another; and/or to optically separate the at least two optical elements from one another.

21. (canceled)

22. An apparatus comprising an optoelectronic module according to claim 1, wherein the apparatus is at least one of: a portable computing device, a cellular telephone, a camera, an image-recording device; and/or a video recording device.
